(19) United States
(12) Patent Application Publication
(10) Pub. No.: US 2003/0198375 A1
(43) Pub. Date: Oct. 23, 2003

(54) Method for reducing data storage requirements for defects identified on semiconductor wafers

(76) Inventor: Yervant D. Lepejian, Palo Alto, CA (US)

Correspondence Address: VICTOR H. OKUMOTO, P.O. BOX 6120, FREMONT, CA, 94538, US

(21) Appl. No.: 10/124,787

(22) Filed: Apr. 17, 2002

(51) Int. Cl. G06K 9/00; G01R 31/26

(52) U.S. Cl. 382/149; 324/765

(57) ABSTRACT

A method for reducing data storage requirements for defects identified on one or more related semiconductor wafers is described. The method includes: receiving images of one or more related semiconductor wafers; identifying defects on the one or more related semiconductor wafers by comparing the received images with corresponding images of a model semiconductor wafer having an identical integrated circuit design as the one or more related semiconductor wafers; and compressing information of the identified defects for data storage.

### FIELD OF THE INVENTION

The present invention generally relates to semiconductor yield analysis techniques and in particular, to a method for reducing data storage requirements for defects identified on semiconductor wafers.

### BACKGROUND OF THE INVENTION

Large semiconductor manufacturing facilities produce thousands of semiconductor wafers per day. To maximize their productivity and profitability, rapid yield improvement is essential. To effectively perform yield analysis, however, information on large numbers of manufactured wafers is required. The resulting storage requirements for defects identified on the semiconductor wafers can be huge, necessitating a large number of expensive storage media as well as complex database and computer security systems to keep track of and protect such voluminous amount of sensitive information.

### OBJECTS AND SUMMARY OF THE INVENTION

Accordingly, it is an object of the present invention to provide a method for reducing data storage requirements for defects identified on semiconductor wafers.

This and additional objects are accomplished by the various aspects of the present invention, wherein briefly stated, one aspect is a method for reducing data storage requirements for defects identified on a semiconductor wafer, comprising: receiving an image of a semiconductor wafer; identifying defects on the semiconductor wafer by comparing the received image with a corresponding image of a model semiconductor wafer having an identical integrated circuit design as the semiconductor wafer; and compressing information of the identified defects for data storage.

Another aspect is a method for reducing data storage requirements for defects identified on related semiconductor wafers, comprising: receiving images of related semiconductor wafers; identifying defects on the related semiconductor wafers by comparing the received images one at a time with corresponding images of a model semiconductor wafer having an identical integrated circuit design as the related semiconductor wafers; and compressing information of the identified defects for data storage.

Still another aspect is a method for reducing data storage requirements for defects identified on a semiconductor wafer, comprising: generating a differential image by subtracting pixel values of an image of a model semiconductor wafer from corresponding pixel values of an image of a semiconductor wafer having a same integrated circuit design as the model semiconductor wafer; generating an image of at least one identified defect from the differential image; and compressing the image of the at least one identified defect for data storage.

Additional objects, features and advantages of the various aspects of the invention will become apparent from the following description of its preferred embodiments, which description should be taken in conjunction with the accompanying drawings.

### BRIEF DESCRIPTION OF THE DRAWINGS

FIG. 1 illustrates, as an example, a flow diagram of a method for reducing data storage requirements for defects identified on one or more related semiconductor wafers, utilizing aspects of the present invention.

FIG. 2 illustrates, as a simplified example, an image of a semiconductor wafer including defects.

FIG. 3 illustrates, as a simplified example, a corresponding image of a model semiconductor wafer.

FIG. 4 illustrates, as an example, a differential image generated by subtracting the corresponding image of the model semiconductor wafer from the image of the semiconductor wafer, according to aspects of the present invention.

FIG. 5 illustrates, as an example, a graphical representation of minimal windows defined on the differential image and individually including an identified defect, according to aspects of the present invention.

### DETAILED DESCRIPTION OF THE PREFERRED EMBODIMENT

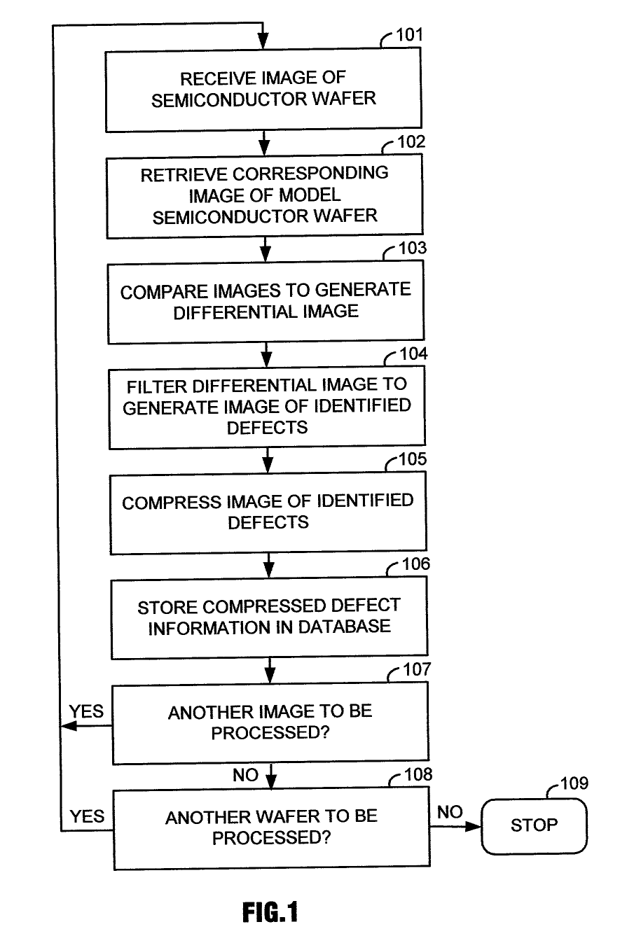

FIG. 1 illustrates a method for reducing data storage requirements for defects identified on one or more semiconductor wafers. The method is preferably implemented as a software program run on a computer.

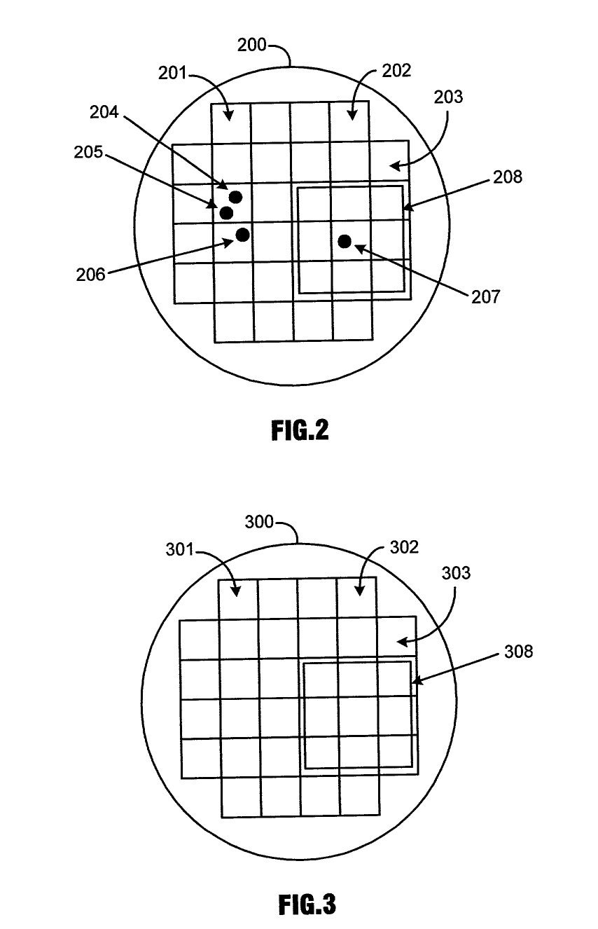

In 101, an image of a semiconductor wafer is received. The image may include the entire semiconductor wafer such as the semiconductor wafer 200 shown in FIG. 2, or it may include only a portion of the semiconductor wafer such as the window 208 of the semiconductor wafer 200 shown in FIG. 2. The image may be of a fully processed or partially processed semiconductor wafer.

A digital camera or other image capturing means situated in or associated with a manufacturing environment for the semiconductor wafer generates the image. The manufacturing environment includes various process stages in the manufacturing line as well as post-process activities such as wafer probe for electrical testing of the wafers. The digital camera or other image capturing means is preferably situated so as to capture the image of the semiconductor wafer during and/or after processing. The format of the received image is preferably suitable for digital processing. Otherwise, conditioning of the image to make it so is desirable.

In 102, an image of a model semiconductor wafer corresponding to the received image in 101 is retrieved from data storage. The model semiconductor wafer in this case has an integrated circuit design that is identical to or the same as that of the semiconductor wafer whose image was received in 101. Its image is also representative of the same processing step or level as the image of the semiconductor wafer received in 101. The model semiconductor wafer is referred to as being a “model”, because it has known defect characteristics. For example, the image of the model semiconductor wafer can be of an actual semiconductor wafer with known defects (i.e., defects whose characteristics and locations on the wafer are known) or it can be of an idealized semiconductor wafer that is “defect free” (i.e., has no defects).

If the received image in 101 includes the entire semiconductor wafer, then the corresponding image of the model semiconductor wafer also includes an image of the entire model semiconductor wafer such as the model semiconductor wafer 300 shown in FIG. 3. On the other hand, if the received image in 101 only includes a portion of the semiconductor wafer, then the corresponding image of the model semiconductor wafer only includes a corresponding portion of the model semiconductor wafer such as the window portion 308 of the model semiconductor wafer 300 shown in FIG. 3 that has wafer related coordinates that corresponds to those of the window portion 208 of the semiconductor wafer 200 shown in FIG. 2.

When the corresponding image only includes a portion of the model semiconductor wafer, the method preferably only retrieves that portion in 102. Alternatively, however, the method may retrieve the entire image of the model semiconductor wafer from storage, then retrieve the corresponding portion of the model semiconductor wafer from the retrieved entire image in 102.

In 103, a differential image is generated by comparing the image of the semiconductor wafer received in 101 with the corresponding image of the model semiconductor wafer retrieved in 102. To perform this comparison, the method preferably subtracts pixel values of the retrieved corresponding image of the model semiconductor wafer from corresponding pixel values of the received image of the semiconductor wafer, so that the common background information such as the integrated circuit design in both images is eliminated and only differences between the two images remain.

In 104, an image of identified defects is generated by filtering the differential image. As examples of such filtering, to compensate for slight offset or other errors in the images, differences that are less than a threshold value are effectively filtered out of the differential image by ignoring them and not including them in the image of identified defects. Also, if the model semiconductor wafer has known defects, then differences caused by such known defects are also effectively filtered out of the differential image by ignoring them and not including them in the image of identified defects. Consequently, such items not included in the differential image are not recognized as defects.

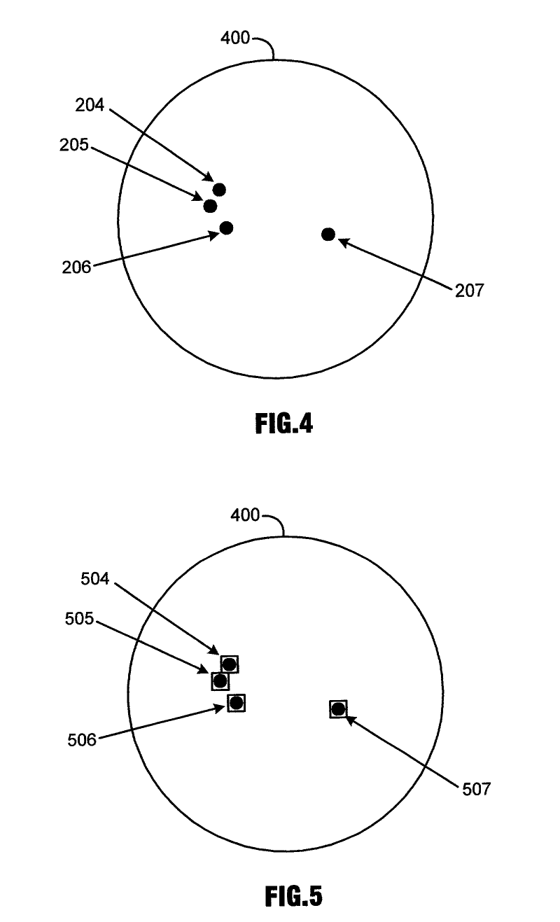

FIGS. 2˜4 illustrate a simple example of the processing to this point. FIG. 2 illustrates an image of a semiconductor wafer 200 including a number of integrated circuit die such as 201, 202 and 203 having a same integrated circuit design. Also shown on the semiconductor wafer 200 are defects 204, 205, 206 and 207. FIG. 3 illustrates an image of a corresponding model semiconductor wafer 300 having integrated circuit die such as 301, 302 and 303 having the same or identical integrated circuit design as their corresponding integrated circuit die 201, 202 and 203 of the semiconductor wafer 200. FIG. 4 illustrates a differential image 400 generated by subtracting the image of the corresponding model semiconductor wafer 300 from the image of the semiconductor wafer 200. Since the only difference between the two images in this example are the defects 204, 205, 206 and 207, these items are the only things appearing in the differential image 400.

In 105, information of the image of identified defects is compressed for data storage. Preferably, this is done by compressing the entire image using a conventional compression format such as JPEG. Since image of identified defects (such as 400 in FIG. 4) is blank everywhere except for the identified defects (such as 204˜207 in FIG. 4), the large areas of blank spaces will be efficiently compressed, thus significantly reducing the data storage requirements for the defects, as compared to the original received image of semiconductor wafer which has many integrated circuit design features on it (such as on semiconductor wafer 200 in FIG. 2) that are not easily compressed using such formats.

Alternatively, to even further reduce storage requirements, minimal windows individually including one of the identified defects can be defined so that their respective images can be compressed for data storage. For example, FIG. 5 illustrates minimal windows 504˜507 defined on the differential image 400 (where the differential image is the same as the image of identified defects in this example to simplify the discussion), respectively including corresponding ones of the defects 204˜207. Since the area outside the minimal windows is defect free, it is blank area. Therefore, it contains no additional information beyond what is already available in the image of the model semiconductor wafer.

In 106, the compressed information of identified defects generated in 105 is stored in a database that is preferably accessible by yield analysis software. When storing compressed image information for minimal windows, coordinate information identifying the position of the window on the semiconductor wafer, a device identifier identifying the integrated circuit design on the wafer, a process step identifier identifying the process step that the image represents, and a wafer identifier identifying the particular semiconductor wafer from which the images came from are also preferably stored. Since the semiconductor wafer 200 and the model semiconductor wafer 300 are identical in size, the stored coordinate information for the windows is applicable to both the semiconductor wafer 200 and the model semiconductor wafer 300.

In 107, it is determined whether another image for the same semiconductor wafer is to be processed (e.g., the window image 208 in FIG. 2). If the answer is YES, then the method jumps back to 101 to process the next image for the same semiconductor wafer. On the other hand, if the answer is NO, then in 108, it is determined whether an image of another of related semiconductor wafers is to be processed. If the answer is YES, then the method jumps back to 101 to process an image for the next of related semiconductor wafers. In that case, the method is said to reduce storage requirements for defects identified on related semiconductor wafers. If the answer is NO, however, the method proceeds to 109 to terminate its present processing.

Although the various aspects of the present invention have been described with respect to a preferred embodiment, it will be understood that the invention is entitled to full protection within the full scope of the appended claims.

I claim:

1. A method for reducing data storage requirements for defects identified on a semiconductor wafer, comprising:
receiving an image of a semiconductor wafer;
identifying defects on said semiconductor wafer by comparing said received image with a corresponding image of a model semiconductor wafer having an identical integrated circuit design as said semiconductor wafer; and
compressing information of said identified defects for data storage.

2. The method according to claim 1, wherein said model semiconductor wafer is substantially defect free.

3. The method according to claim 1, wherein said model semiconductor wafer includes known defects.

4. The method according to claim 1, wherein said receiving an image of a semiconductor wafer, comprises receiving an image of a semiconductor wafer in a form suitable for digital processing.

5. The method according to claim 4, wherein said receiving an image of a semiconductor wafer in a form suitable for digital processing, comprises receiving an image generated by a digital camera.

6. The method according to claim 5, wherein said receiving an image generated by a digital camera, comprises receiving an image generated by a digital camera situated in a manufacturing environment for said semiconductor wafer.

7. The method according to claim 1, wherein said received image is digitized, and said identifying defects on said semiconductor wafer by comparing said received image with a corresponding image of a model semiconductor wafer having an identical integrated circuit design as said semiconductor wafer, comprises identifying defects on said semiconductor wafer by subtracting corresponding pixel values of said received digitized image and a corresponding digitized image of said model semiconductor wafer.

8. The method according to claim 7, wherein said identifying defects on said semiconductor wafer by comparing said received image with a corresponding image of a model semiconductor wafer having an identical integrated circuit design as said semiconductor wafer, further comprises ignoring differences between corresponding pixel values of said received digitized image and said corresponding digitized image of said model semiconductor wafer if said differences are less than a threshold value.

9. The method according to claim 7, wherein said identifying defects on said semiconductor wafer by comparing said received image with a corresponding image of a model semiconductor wafer having an identical integrated circuit design as said semiconductor wafer, further comprises ignoring differences between corresponding pixel values of said received digitized image and said corresponding digitized image of said model semiconductor wafer if said differences are caused by known defects.

10. The method according to claim 1, wherein said image of said semiconductor wafer represents a portion of said semiconductor wafer, and said corresponding image of said model semiconductor wafer represents a corresponding portion of said model semiconductor wafer.

11. The method according to claim 1, further comprising storing said compressed information of said identified defects in a database.

12. The method according to claim 10, wherein said database is accessible by yield analysis software.

13. The method according to claim 1, wherein said compressing information of said identified defects for data storage, comprises compressing image files of minimal windows individually including one of said identified defects for data storage.

14. The method according to claim 13, further comprising storing coordinate information of said minimal windows relative t o said s em i conductor wafer indicating locations of said minimal windows in said image of said semiconductor wafer.

15. The method according to claim 1, wherein said compressing information of said identified defects for data storage, comprises compressing at least one image file including at least one of said identified defects in JPEG format.

16. A method for reducing data storage requirements for defects identified on related semiconductor wafers, comprising:
receiving images of related semiconductor wafers;
identifying defects on said related semiconductor wafers by comparing said received images one at a time with corresponding images of a model semiconductor wafer having an identical integrated circuit design as said related semiconductor wafers; and
compressing information of said identified defects for data storage.

17. The method according to claim 16, wherein said model semiconductor wafer is substantially defect free.

18. The method according to claim 16, wherein said model semiconductor wafer includes known defects.

19. The method according to claim 16, wherein said receiving images of related semiconductor wafers, comprises receiving images of related semiconductor wafers in a form suitable for digital processing.

20. The method according to claim 19, wherein said receiving images of said related semiconductor wafers in a form suitable for digital processing, comprises receiving images generated by one or more digital cameras.

21. The method according to claim 20, wherein said receiving images generated by one or more digital cameras, comprises receiving images generated by one or more digital cameras situated in one or more manufacturing environments for said related semiconductor wafers.

22. The method according to claim 16, wherein said received images are digitized, and said identifying defects on said related semiconductor wafers by comparing said received images one at a time with corresponding images of a model semiconductor wafer having an identical integrated circuit design as said related semiconductor wafers, comprises identifying defects on said related semiconductor wafers by subtracting corresponding pixel values of said received digitized images and corresponding digitized images of said model semiconductor wafer.

23. The method according to claim 22, wherein said received images are digitized, and said identifying defects on said related semiconductor wafers by comparing said received images one at a time with corresponding images of a model semiconductor wafer having an identical integrated circuit design as said related semiconductor wafers, further comprises ignoring differences between corresponding pixel values of said received digitized images and said corresponding digitized images of said model semiconductor wafer if said differences are less than a threshold value.

24. The method according to claim 22, wherein said received images are digitized, and said identifying defects on said related semiconductor wafers by comparing said received images one at a time with corresponding images of a model semiconductor wafer having an identical integrated circuit design as said related semiconductor wafers, further comprises ignoring differences between corresponding pixel values of said received digitized images and said corresponding digitized images of said model semiconductor wafer if said differences are caused by known defects.

25. The method according to claim 16, wherein said images of said related semiconductor wafer represent portions of said semiconductor wafer, and said corresponding images of said model semiconductor wafer represent corresponding portions of said model semiconductor wafer.

26. The method according to claim 16, further comprising storing said compressed information of said identified defects in a database.

27. The method according to claim 26, wherein said database is accessible by yield analysis software.

28. The method according to claim 16, wherein said compressing information of said identified defects for data storage, comprises compressing image files of minimal windows individually including one of said identified defects for data storage.

29. The method according to claim 28, further comprising storing coordinate information of said minimal windows relative to their respective related semiconductor wafer indicating locations of said minimal windows in said respective related semiconductor wafer.

30. The method according to claim 16, wherein said compressing information of said identified defects for data storage, comprises compressing at least one image file including at least one of said identified defects in JPEG format.

31. A method for reducing data storage requirements for defects identified on a semiconductor wafer, comprising:
generating a differential image by subtracting pixel values of an image of a model semiconductor wafer from corresponding pixel values of an image of a semiconductor wafer having a same integrated circuit design as said model semiconductor wafer;
generating an image of at least one identified defect from said differential image; and
compressing said image of said at least one identified defect for data storage.

32. The method according to claim 31, wherein said generating an image of at least one identified defect, comprises filtering said differential image by ignoring differences between corresponding pixel values of said image of said model semiconductor wafer and said image of said semiconductor wafer if said differences are less than a threshold value.

33. The method according to claim 31, wherein said model semiconductor wafer includes known defects, and said generating an image of at least one identified defect, comprises filtering said differential image by ignoring differences between corresponding pixel values of said image of said model semiconductor wafer and said image of said semiconductor wafer if said differences are caused by said known defects.

34. The method according to claim 31, wherein said compressing said image of said at least one identified defect for data storage, comprises:
generating image files of minimal windows individually including one of said at least one identified defects; and
compressing said image files for data storage.

35. The method according to claim 34, further comprising storing coordinate information of said minimal windows relative to said semiconductor wafer indicating locations of said minimal windows in said image of said semiconductor wafer.

36. The method according to claim 34, wherein said compressing said image files for data storage, comprise compressing said image files in JPEG format for data storage.

37. The method according to claim 31, wherein said compressing said image of said at least one identified defect for data storage, comprises compressing at least one image file including at least one of said at least one identified defects in JPEG format.
